(19) United States
(12) Patent Application Publication
(10) Pub. No.: US 2026/0005114 A1
(43) Pub. Date: Jan. 1, 2026

(54) FRAMES FOR GLASS CORE HYBRID PANELS

(71) Applicant: Intel Corporation, Santa Clara, CA (US)

(72) Inventors: Benjamin T. Duong, Phoenix, AZ (US); Pratyush Mishra, Tempe, AZ (US); Robert A. May, Chandler, AZ (US); Soham Agarwal, Chandler, AZ (US); Kristof Darmawikarta, Chandler, AZ (US); Gang Duan, Chandler, AZ (US); Jeremy D. Ecton, Gilbert, AZ (US); Jung Kyu Han, Chandler, AZ (US); Thomas S. Heaton, Gilbert, AZ (US); Kari E. Hernandez, Phoenix, AZ (US); Tarek A. Ibrahim, Mesa, AZ (US); Andrew Matthew Jimenez, Mesa, AZ (US); Brandon Christian Marin, Gilbert, AZ (US); Lilia May, Chandler, AZ (US); Pratyasha Mohapatra, Hillsboro, OR (US); Son Van Nguyen, Gilbert, AZ (US); Srinivas Venkata Ramanuja Pietambaram, Chandler, AZ (US); Bohan Shan, Chandler, AZ (US); Hiroki Tanaka, Gilbert, AZ (US); David Vickery, Gilbert, AZ (US); Yekan Wang, Chandler, AZ (US); Zhixin Xie, Chandler, AZ (US)

(73) Assignee: Intel Corporation, Santa Clara, CA (US)

(21) Appl. No.: 18/755,957

(22) Filed: Jun. 27, 2024

(51) Int. Cl. H01L 23/498; H01L 21/48; H01L 23/15

(52) U.S. Cl. CPC H01L 23/49822; H01L 23/15; H01L 23/49827; H01L 21/481

(57) ABSTRACT

Architectures and process flows for frames for glass core hybrid panels for semiconductor packaging. The glass core includes a layer of glass defined by a planar area enclosed by one or more edges that are substantially orthogonal to the planar area and at least one through-glass via (TGV) in the layer of glass, substantially filled with a conductive material. The frame comprises a coefficient of thermal expansion (CTE) that can be manipulated based on selection of frame material and/or percentage of copper in the frame material. The frame has a CTE of less than 11. The frame can enclose a panel, sub-panel or wafer and can include one or more cavities therein for respective glass cores.

### BACKGROUND

Many semiconductor package architectures include a layer of glass or glass core to improve the dimensional stability of the substrate package; the improved dimensional stability enables placing more die on a single substrate package. However, the layer of glass can introduce technical challenges in the manufacturing process. Accordingly, improved architectures and methodologies for implementing a glass core are desired.

### BRIEF DESCRIPTION OF THE DRAWINGS

FIG. 1 is a simplified illustration of an example layer of glass, in accordance with various embodiments.

FIG. 2 provides simplified top-down views of a frame implemented with a panel and a quarter panel, in accordance with an embodiment.

FIGS. 3A, 3B, 3C, and 3D are simplified cross-sectional views of embodiments of frames for glass core hybrid panels at different process steps, in accordance with a first aspect of the disclosure.

FIG. 4 illustrates an example method for manufacturing and implementing frames for glass core hybrid panels, in accordance with embodiments depicted in FIGS. 3A-3D.

FIGS. 5A, 5B, 5C, and 5D, are simplified cross-sectional views of various embodiments of frames for glass core hybrid panels at different process steps, in accordance with another aspect of the disclosure.

FIG. 6 illustrates an example method for manufacturing and implementing frames for glass core hybrid panels, in accordance with embodiments depicted in FIGS. 5A-5D.

FIG. 7 is a simplified illustration of an exemplary system that may be built up on the glass core hybrid panels, in accordance with an embodiment.

FIG. 8 is another simplified illustration of an exemplary system that may be built up on the glass core hybrid panels, in accordance with an embodiment.

FIG. 9 is a top view of a wafer and dies that may be included in a microelectronic assembly, in accordance with any of the embodiments disclosed herein.

FIG. 10 is a simplified cross-sectional side view showing an implementation of an integrated circuit on a die that may be included in various embodiments, in accordance with any of the embodiments disclosed herein.

FIG. 11 is a cross-sectional side view of a microelectronic assembly that may include any of the embodiments disclosed herein.

FIG. 12 is a block diagram of an example electrical device that may include any of the embodiments disclosed herein.

### DETAILED DESCRIPTION

Many semiconductor package architectures utilize a layer of glass in an active area of a substrate component (“glass core hybrid components”), to attain smaller pitches and provide dimensional stability of the substrate package. Consequently, package architectures that implement glass cores can enable one larger, more complex die, and/or can enable placing more heterogeneous dies on a single substrate component, thereby resulting in more complex systems than a package architecture without a glass layer.

However, to be competitive, glass core hybrid components have to be fungible with existing organic substrate components during the manufacturing process. One way to do that is to reconstitute them into a panel, a quarter panel, or a wafer for manufacturing. Often this is achieved by individually encapsulating the glass cores with mold or a dielectric material to reconstitute them into a desired planar area (the panel, quarter panel, or wafer) with a frame. One of the technical challenges that occurs with these reconstituted glass core panels is warpage of the frame, which can be induced by temperature or mechanical stresses and can reduce yield; glass is brittle (with a low coefficient of thermal expansion (CTE)) and when the frame, comprising a higher CTE, warps, responding to external stress, it can fracture the glass core. As may be appreciated, the thinner the layer of glass comprising the glass core, the more delicate and subject to warpage it becomes. Additionally, the glass cores can separate from the mold or dielectric material around them.

Many frames are made with a copper clad laminate (CCL) material. The CCL can have glass fibers and resin in the center, with copper around the fibers and resin. As used herein, resin has the plain English definition of a synthetic organic polymer. The CCL frames enable handling of the glass cores, but technical challenges remain.

Embodiments described herein provide a technical solution to this technical challenge, and other advantages, in the form of methods and architectures for frames for glass core panels. Embodiments enable creating glass core hybrid components on the existing organic substrate manufacturing infrastructure/tools. As used herein, a hybrid panel includes a central glass core, which is embedded in a surrounding frame. Embodiments enable control over the CTE of the frame and reduce warpage. The practice of embodiments can be identified in reconstituted wafers, sub-panels, and panels, which may be transferred between sites or suppliers, in addition to reviewing documentary information about process flows.

Example embodiments are hereinafter described in conjunction with the following drawing figures, wherein like numerals denote like elements. Figures are not necessarily to scale but may be relied on for spatial orientation and relative positioning of features. As may be appreciated, certain terminology, such as “ceiling” and “floor”, as well as “upper,”, “uppermost”, “lower,” “above,” “below,” “bottom,” and “top” refer to directions based on viewing the Figures to which reference is made. Further, terms such as “front,” “back,” “rear,”, “side”, “vertical”, and “horizontal” may describe the orientation and/or location of portions of the component within a consistent but arbitrary frame of reference which is made clear by reference to the text and the associated Figures describing the component under discussion. Such terminology may include the words specifically mentioned above, derivatives thereof, and words of similar import.

As used herein, the term “adjacent” refers to layers or components that are in direct physical contact with each other, with no layers or components in between them. For example, a layer X that is adjacent to a layer Y refers to a layer that is in direct physical contact with layer Y. In contrast, as used herein, the phrase(s) “located on” (in the alternative, “located under,” “located above/over,” or “located next to,” in the context of a first layer or component located on a second layer or component) includes (i) configurations in which the first layer or component is directly physically attached to the second layer (i.e., adjacent), and (ii) component and configurations in which the first layer or component is attached (e.g. coupled) to the second layer or component via one or more intervening layers or components.

The following detailed description is not intended to limit the application and use of the disclosed technologies. It may be evident that the novel embodiments can be practiced without every detail described herein. For the sake of brevity, well-known structures and devices may be shown in block diagram form to facilitate a description thereof.

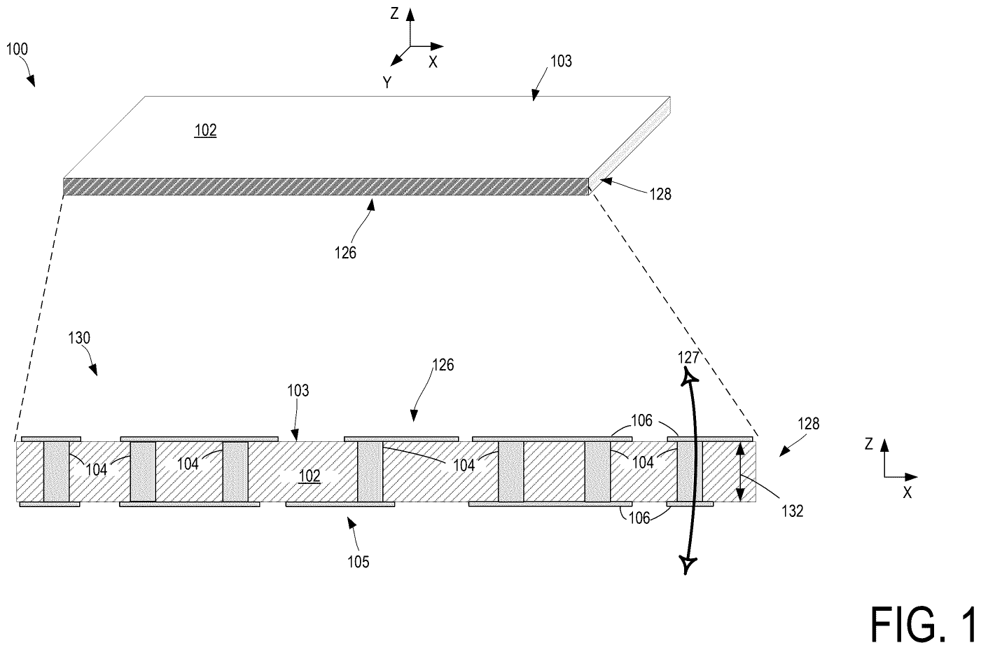

The non-limiting example in FIG. 1 is a simplified illustration of an example glass core or layer of glass. Image 100 provides a framework for the layer of glass 102 in three dimensions, image 130 depicts the layer of glass 102 in an X-Z cross-sectional view. The layer of glass 102 is a rectangular prism volume with a planar area, upper surface 103, and one or more perimeter edges (e.g., perimeter edge 126 and perimeter edge 128). The perimeter edges have a thickness of 132 and respective lengths. Image 130 further depicts that the layer of glass 102 may be patterned with conductive traces or redistribution layers 106 on the upper surface 103 and may have at least one electrical path (illustrated with cartoon arrow 127) from the upper surface 103 of the layer of glass to the lower surface 105 of the layer of glass (through a through-glass via (TGV 104) comprising a conductive material).

The layer of glass 102 comprises a solid layer of “glass.” As used herein, glass may comprise Silicon and Oxygen, as well as any one or more of Aluminum, Boron, Magnesium, Calcium, Barium, Tin, Sodium, Potassium, Strontium, Phosphorus, Zirconium, Lithium, Titanium, and Zinc. Non-limiting examples of glass include aluminosilicate, borosilicate, alumino-borosilicate, silica, and fused silica. In various embodiments, the glass may further include one or more additives, such as Al2O3, B2O3, MgO, CaO, SrO, BaO, SnO2, Na2O, K2O, SrO, P2O3, ZrO2, Li₂O, Ti, and Zn.

In some embodiments, the glass comprises at least 23 percent Silicon and at least 26 percent Oxygen by weight, and further comprises at least 5 percent Aluminum by weight. In some embodiments, the glass may be a photosensitive glass that belongs to the lithium-silicate family of glass (e.g., a glass comprising lithium, silicon, and oxygen) comprising metallic particles, such as gold, silver, or other suitable metallic particles. The layer of glass 102 may comprise multiple glass sheets bonded together with an adhesion layer. The glass in the layer of glass 102 does not include an organic adhesive and the glass does not include an organic material.

In various embodiments, the thickness 132 (i.e., the Z direction in FIG. 1) ranges from 20 microns+/−10% to 2 millimeters (mm)+/−10%. In various embodiments, the layer of glass 102 has a planar area (i.e., the Y-X directions in image 100) that is defined by one or more perimeter edges that are substantially orthogonal or perpendicular (i.e., 90 degrees plus or minus 18 degrees) to the planar area, the edges can have a length in a range of 10 millimeters (mm)+/−20% to 500 millimeters+/−20% (e.g., a panel can be 10 millimeters×10 millimeters up to 500 millimeters×500 millimeters). In other embodiments, the layer of glass may embody the planar area of a quarter panel or of a wafer. In the embodiment of the layer of glass 102, the glass comprises a rectangular prism volume with sections removed, those sections being the through-glass vias (TGV 104).

Variations of the embodiment of FIG. 1 advantageously can be reconstituted into a larger planar area (such as a wafer, quarter panel, or panel) in which the layer of glass 102 is one of a plurality of similar layers of glass; the layers of glass individually located in a frame, with a mold or dielectric material securing the respective layers of glass 102 between the frame and the layer of glass 102. The reconstituted planar area is fungible with existing manufacturing flows for organic substrate components, and can be stored/transported, or timely subjected to build up with further processing.

For simplicity, the “reconstituted larger planar area” may be referred to as a reconstituted panel herein for simplicity, but those with skill in the art will recognize that, in other embodiments, the reconstituted larger planar area may instead be a quarter panel or a wafer. In an embodiment, the reconstituted planar area may comprise a (X-Y) range of 10 millimeters+/−20% to 250 millimeters+/−20% (e.g., reconstituted into a panel that can be 10 millimeters×10 millimeters up to 250 millimeters×250 millimeters.

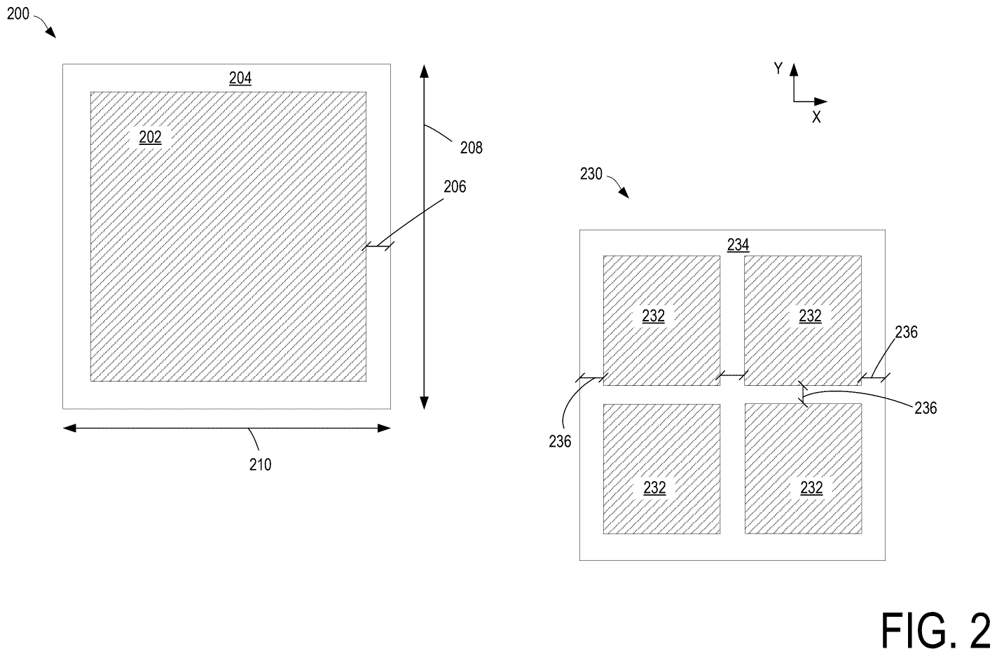

As may be appreciated, the frame may be implemented in various embodiments. FIG. 2 provides a simplified top-down view (embodiment 200) of a frame 204 implemented with a panel 202 and a simplified top-down view (embodiment 230) of a frame 234 implemented with a quarter panel (232) arrangement, in accordance with an embodiment.

In various embodiments, the frame 204/234 has a width 206/236 in a range of 2 millimeters (mm)+/−10% to 15 mm+/−10%. In other embodiments, the frame 204/234 has a width 206/236 in a range of 0.5 millimeters (mm)+/−10% to 20 mm+/−10%. In various embodiments, the frame 204/234 has a Z height (Z being an axis into and out of the page in FIG. 2) in a range of 0.2 mm+/−10% to 0.3 mm+/−10%. In other embodiments, the frame 204/234 has a Z height in a range of 0.1 mm+/−10% to 5 mm+/−10%. As mentioned, the frame is external to or outside the perimeter of the glass core or layer of glass. In the exemplary panel 202 embodiment, the outer dimensions of the hybrid panel may be described as a planar area with a length and width, for example, length 208 and width 210, wherein the length 208 comprises the respective length of the glass panel 202 plus twice the frame width, and the width 210 comprises the respective width of the glass panel 202 plus twice the frame width. Other hybrid panels can be evaluated similarly, by adding together the widths and lengths of the glass panels plus the number of frame widths in the embodiment.

Suitable frame materials vary. The selection of the frame material can be informed by the desired CTE, as well as fabrication tolerances. For example, using a frame material with a CTE closer to the CTE of glass reduces damage from warpage. Glass can have a CTE in a range of 1-8 ppm/degree C. In some embodiments, the frame material is a metal, in other embodiments, the frame material is an alloy. Also, as mentioned, the frame material can further include glass fibers and resin. Example fame materials include Kovar®, Invar®, and Stainless Steel®.

In other embodiments, the frame material includes copper, and adds Tungsten (W) to the copper, using various percentages®. Copper has a CTE of 17 ppm/degree C., a resistivity of 1.7 mW/cm, and a Young's modulus of 120 GPa while a frame material comprising 0.25 Cu and 0.75 W has a CTE of 10 ppm/degree C., resistivity of 3.5 mW/cm and a Young's modulus of 280 GPa. By varying the Cu concentration, frames can be created with a diverse range of CTEs and resistivities to target product needs. In an example embodiment, the frame material is CuW, with copper in a range of 1% to 99% and a remainder of Tungsten+/−1%, meaning Tungsten in a range of 99% to 1%. In another embodiment, the frame material is CuW, with copper in a range of 20%-50% and a remainder of Tungsten, meaning that Tungsten is in a range of 80% to 50%.

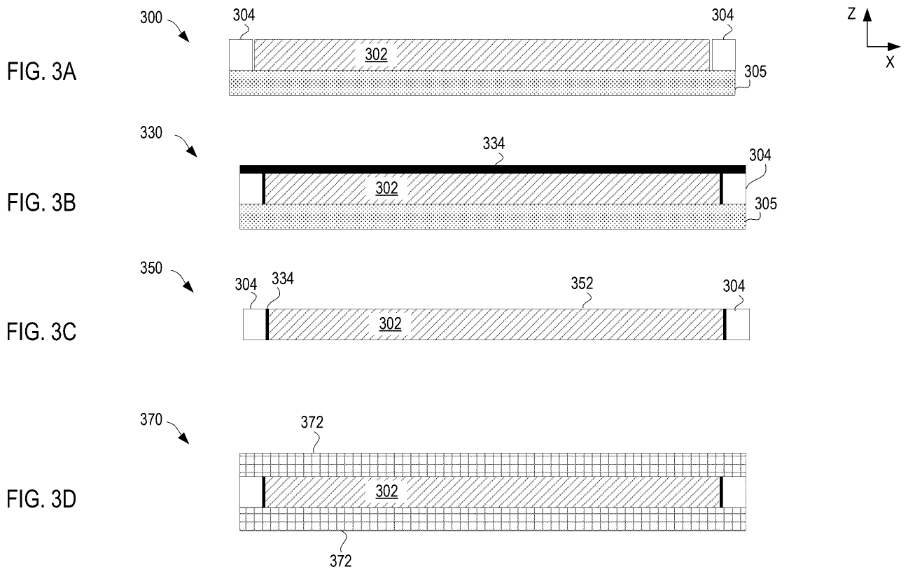

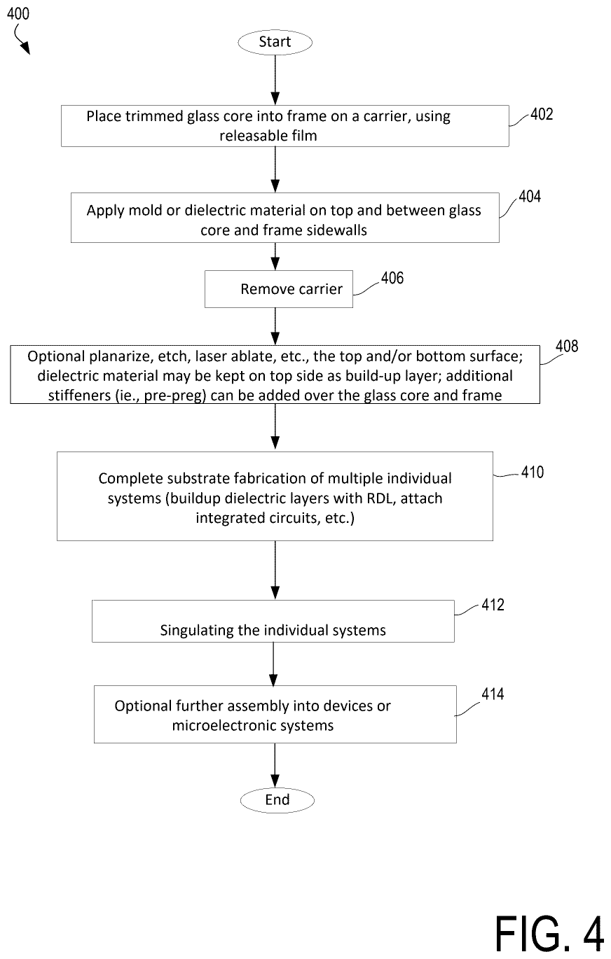

FIGS. 3A, 3B, 3C, and 3D are simplified cross-sectional views of embodiments of frames for glass core hybrid panels at different process steps, in accordance with a first aspect of the disclosure, and FIG. 4 illustrates an example method 400 for manufacturing and implementing frames for glass core hybrid panels, in accordance with embodiments depicted in FIGS. 3A-3D.

At 402, individual glass cores 302 are trimmed into desired dimensions and placed into a frame 304 attached on a carrier 305, as shown in embodiment 300. In practice, the frame may be constructed first, to comprise the materials and qualities described hereinabove. With reference to FIG. 2, the frame has at least one region or cavity with continuous sidewalls and open at the top and the bottom (looks sort of like a windowpane, as shown in FIG. 2); the one or more cavities are created in the frame to receive one or more respective glass core(s) 202/232/302. The glass core 302 and frame are both detachably attached to the carrier, using a releasable film, a temporary bond film (TBF), laser release film, or the like (not shown). At 404, mold or a dielectric material 334 is applied on the upper surface 103 and in between the glass core 302 and the frame 304, as illustrated in embodiment 330.

At 406 the carrier is removed, as shown in embodiment 350. The carrier may be reusable, as it was removably attached. At 408, the top surface 352 may be further prepared for substrate fabrication. Tasks at 408 may include optionally planarizing, etching or laser ablating the top surface and bottom surface, although depicted as removed in embodiment 350, in other embodiments, the dielectric material 334 may be left on the top surface 352 as a build-up layer, and additional stiffeners such as pre-preg can be added over the glass core 302 and frame 304 . . . . A pre-preg refers to any C-stage epoxy laminate that has glass cloth (GC) impregnated within it; this makes pre-preg generally stiffer than general epoxy thin films used for buildup which use no GC.

At 410, substrate fabrication may be completed, building up multiple individual systems comprising dielectric layers with RDL therein (372), and attaching one or more integrated circuits (ICs). In the first example, the fabricated panel or quarter panel comprises one large multi-die system. In another example, the fabricated panel or quarter panel comprises a plurality of similar units, each to be singulated at 412 into respective system packages. At 414, optionally, further assembly into devices or microelectronic systems may be performed.

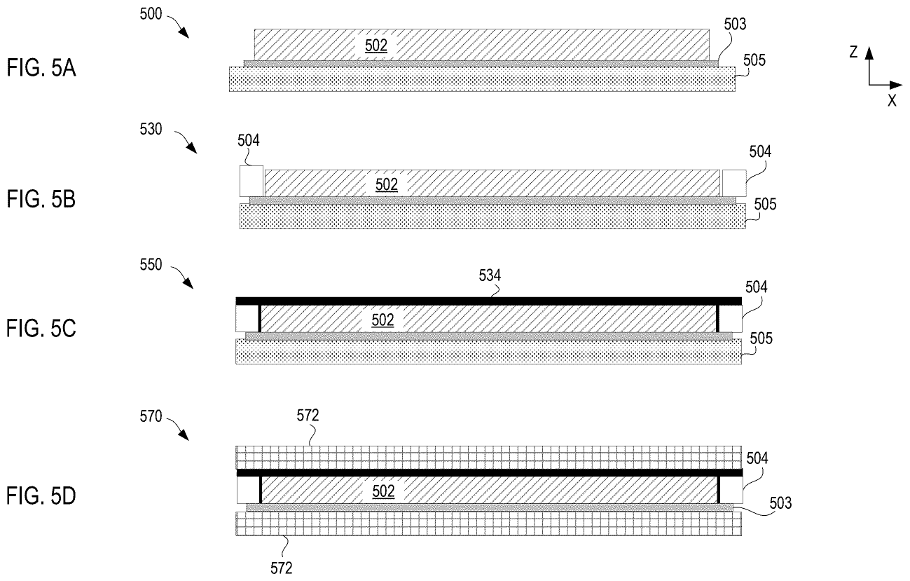

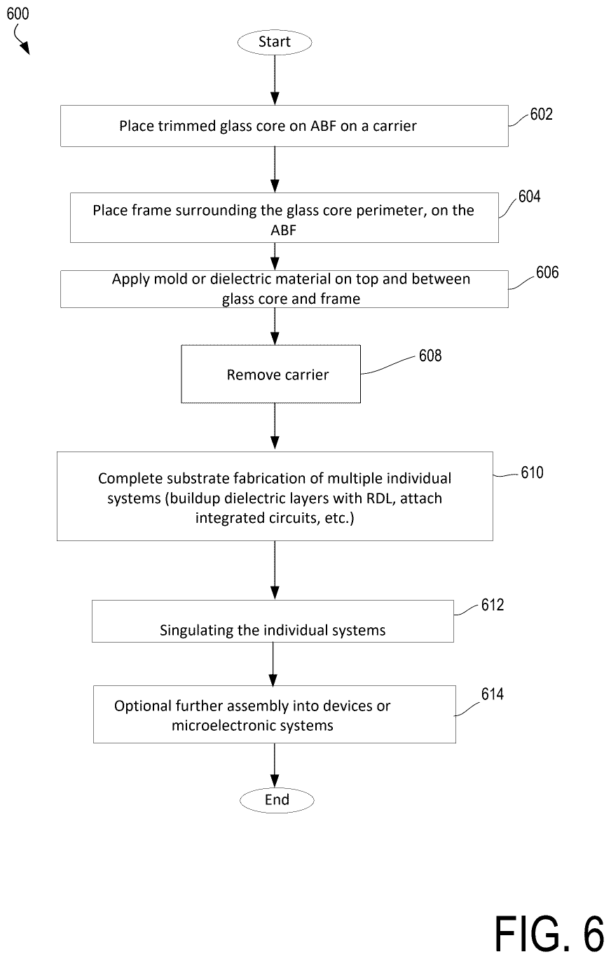

FIGS. 5A, 5B, 5C, and 5D are simplified cross-sectional views of various embodiments of frames for glass core hybrid panels at different process steps, in accordance with another aspect of the disclosure, and FIG. 6 illustrates an example method 600 for manufacturing and implementing frames for glass core hybrid panels, in accordance with embodiments depicted in 5A, 5B, 5C, and 5D.

At 602, a trimmed glass core 502 is placed on a dielectric material 503 or Ajinomoto Build-Up film (ABF) on a carrier 505, as depicted in embodiment 500. At 604, a frame 504 is placed surrounding the glass core 502 perimeter, on the ABF or dielectric material 503, as depicted in embodiment 530. At 606, mold or dielectric material 534 is applied on the upper surface of the glass core and between the glass core and the frame, as depicted in embodiment 550. At 608, the carrier 505 is removed, as depicted in embodiment 570.

At 610, similar to 410, substrate fabrication may be completed, building up multiple individual systems comprising dielectric layers with RDL therein (572), and attaching one or more integrated circuits (ICs). In the first example, the fabricated panel or quarter panel comprises one large multi-die system. In another example, the fabricated panel or quarter panel comprises a plurality of similar units, each to be singulated at 612 into respective system packages. At 614, optionally, further assembly into devices or microelectronic systems may be performed.

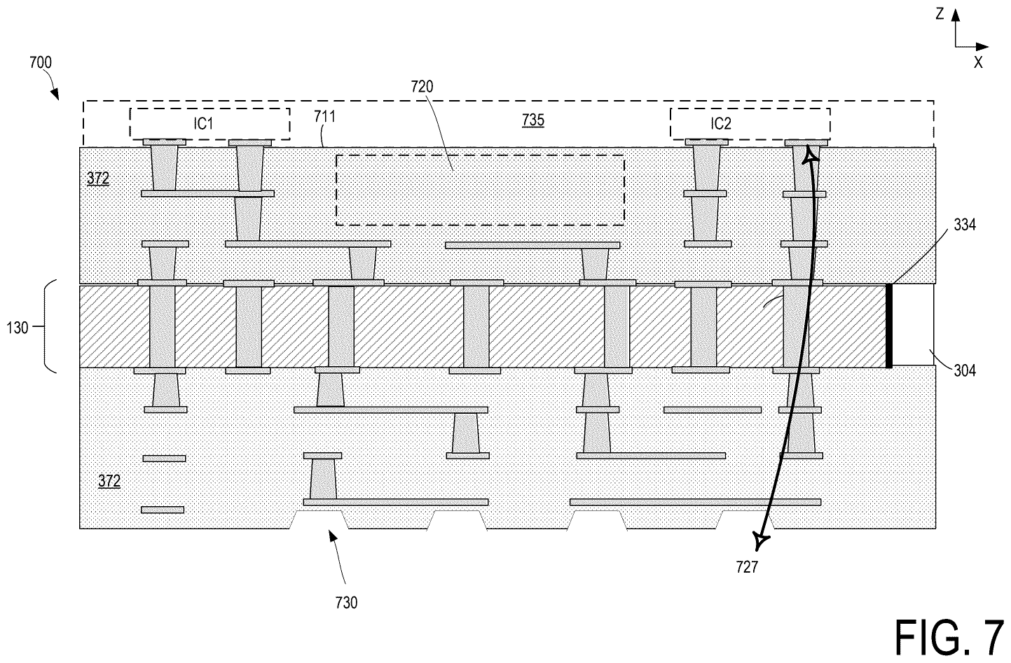

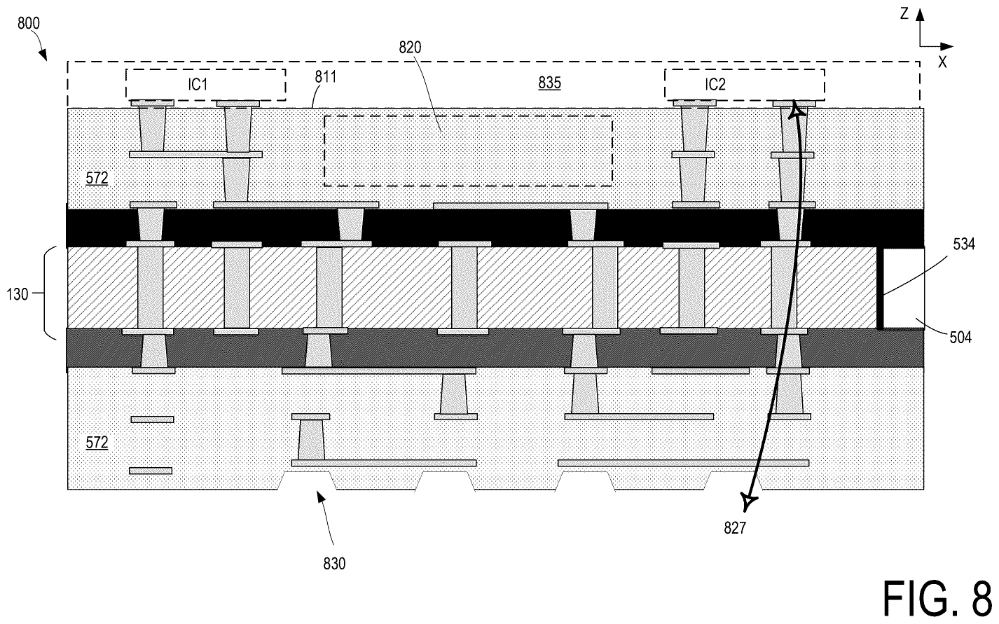

FIG. 7 and FIG. 8 illustrate some non-limiting systems and apparatuses that may implement the provided glass core hybrid components. FIG. 7 illustrates exemplary substrate package 700, with the glass core from image 130 and references embodiment 370, in which dielectric material with RDL therein (372) is on the upper surface and on the bottom surface of the glass core in image 130. FIG. 8 illustrates exemplary substrate package 800, with the glass core from image 130 and references embodiment 570, in which dielectric material with RDL therein (572) is on the upper surface and on the bottom surface of the glass core in image 130. The substrate package view is sometimes referred to as a “substrate patch.” In practice, substrate package 700 and substrate package 800 may be part or all of a system.

The dashed boxes indicate optional variations, e.g., having one or more integrated circuits (ICs) attached on the upper surface 711/811 of the substrate package 700/800, the ICs being overmolded or overlaid with an encapsulant 735/835, and/or having an embedded bridge component 720/820. At least one electrical path 727/827 may travel from the upper surface 711/811 to a lower surface where solder bumps may be attached at locations 730/830. Depending on the singulation protocol and how many units or systems were in between frames 304/504, a portion of a frame 304/504 may be included in the substrate package.

Described differently, the glass core in image 130 is sandwiched between dielectric layers with RDL therein 372/572 that include respective redistribution layers (RDL); the dielectric layers are substantially coplanar with the layer of glass, i.e., extending laterally left to right (along the X axis) above and below the glass core in the figures; as illustrated

The mold or dielectric material 334/534 at least partially fills the cavity created between the frame and the glass core. The dielectric layers comprise a dielectric material 334/534, such as, a suitable nitride or oxide like silicon dioxide (SiO₂), carbon-doped silicon dioxide (C-doped SiO₂, also known as CDO or organosilicate glass, which is a material that comprises silicon, oxygen, and carbon), fluorine-doped silicon dioxide (F-doped SiO₂, also known as fluorosilicate glass, which is a material that comprises fluorine, silicon, and oxygen), or hydrogen-doped silicon dioxide (H-doped SiO₂, which is a material that comprises silicon, oxygen, and hydrogen). In some embodiments, the dielectric material comprises a photo-imageable dielectric (PID). In some embodiments, the dielectric material comprises an Ajinomoto Build-Up film (often referred to as ABF), which is a material that comprises an organic resin matrix with different types of fillers (for example, silica fillers of different sizes, or hollow fillers of different sizes) to control the coefficient of thermal expansion (CTE) and/or electrical properties (e.g., the dielectric constant (Dk), and/or dissipation factor (insertion loss) (Df)).

In some embodiments, it is advantageous for the dielectric material 334/534 to have a CTE that matches that of target dies (e.g., match the CTE of silicon in an IC die such as IC1 and IC2 attached thereto). In some embodiments, the dielectric material can have a CTE that is close (e.g., within 10%) to that of silicon. In other embodiments, the dielectric material can be any type of epoxy molding compound.

The RDL embodies electrical interconnections and electrical paths, or conductive traces, layered and built into the dielectric layers, as is known in the art. As used herein, redistribution layers (RDL) comprise metal or conductive traces or interconnects that connect or provide electrical paths between one region in a substrate package 700/800 to another region and are sufficient for electrical communication and/or for supplying power and ground. The RDL may be implemented in a “core geometry,” such as a 9/12 geometry (meaning a conductive trace width of 9 microns and a spacing of 12 microns). The RDL may comprise a metal (e.g., copper, aluminum, nickel, cobalt, iron, tin, gold, silver, or combinations thereof) or another suitable conductive material. The RDL may have a thickness (measured in the Z direction in the figure) from about 1 micron to 10 microns. In various embodiments, the RDL may be substantially 5 microns. The RDL patterning may be performed using a modified semi-additive plating (MSAP) process, placing the RDL. Pillars or vias provide vertical connectivity between layers of RDL, and also comprise conductive material, and may be the same material as the conductive traces.

Although dielectric layers with RDL therein 372/572 are each illustrated as one continuous dielectric layer, those with skill will appreciate that the dielectric layers often each comprise 2 or more sub-dielectric layers, in a 1:1 relationship with the number of RDL layers. For example, in FIG. 7, three RDL layers are depicted in dielectric layer with RDL therein 372 on the upper surface and four RDL layers are depicted in dielectric layer with RDL therein 372 below the glass core, this is a non-limiting example.

The glass core in image 130 is patterned with through-holes or through glass vias (TGVs) that enable communication between the conductive traces and vias in the dielectric layer with RDL therein 372/572 on the upper surface and the conductive traces in the dielectric layer with RDL therein 372/572 on the lower surface.

In various embodiments, such as when implemented in a packaged assembly, system, or a device, one or more die (e.g., IC1 and IC2) are attached to the substrate package 700/800 and then the die may be overmolded with an encapsulant 735/835. The encapsulant can comprise a molding compound, dielectric materials, metal, ceramic, plastic, or a combination thereof. Additionally, a thermal management solution (not shown) comprising a cooling component such as a vapor chamber, heat pipe, heat sink, or liquid-cooled cold plate may be attached to a substrate package 700/800. As part of a thermal management solution, a thermal conduction layer interface material (TIM) may be located over the die attached to the substrate package 700/800. The TIM can be any suitable material, such as a silver particle-filled thermal compound, thermal grease, phase change materials, indium foils, or graphite sheets. The thermal management solution can be a conformal solution that accommodates differences in heights of the integrated circuit dies for which the thermal management solution provides cooling. For example, a thermal management solution can comprise a substantially planar cooling component with TIMs of varying thickness between the cooling component and the integrated circuit dies. In another example, the cooling component is non-planar, and the profile of the cooling component can vary with the thickness of the integrated circuit dies for which the cooling component provides cooling. In such embodiments, the TIM can be of substantially uniform thickness between the cooling component and the integrated circuit dies of varying thicknesses. Thermal management solutions can also include an integrated heat spreader.

Thus, various non-limiting embodiments of frames for glass core panels have been described. The following description provides additional details and context for various die and various package assembly and device configurations that can be created based on or using the provided embodiments.

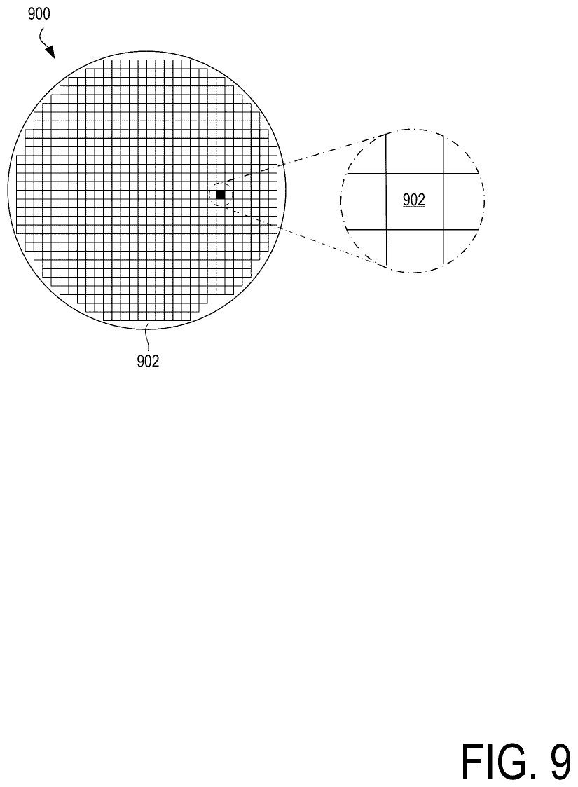

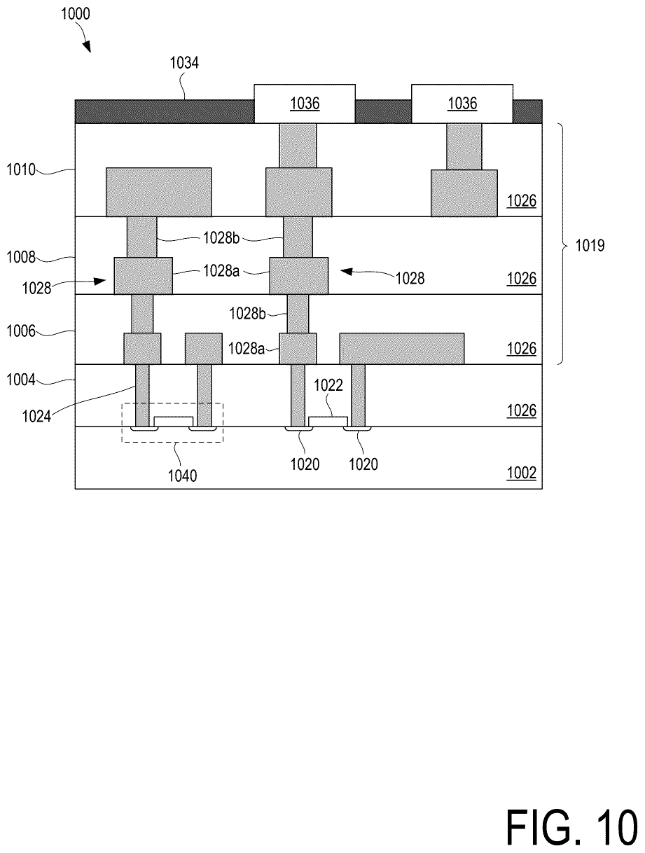

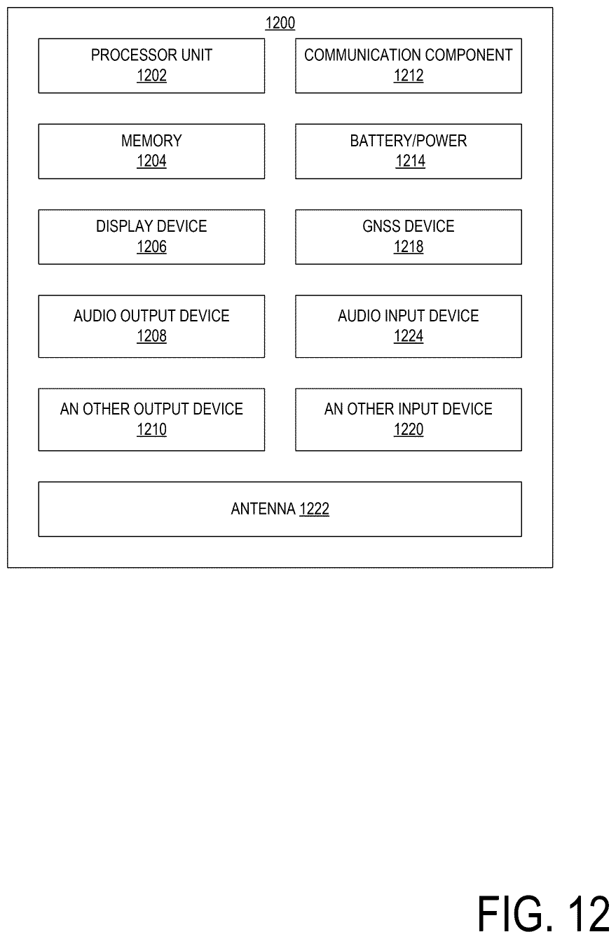

FIG. 9 is a top view of a wafer 900 and dies 902 that may be included in any of the embodiments disclosed herein. The wafer 900 may be composed of semiconductor material and may include one or more dies 902 formed on a surface of the wafer 900. After the fabrication of the integrated circuit components on the wafer 900 is complete, the wafer 900 may undergo a singulation process in which the dies 902 are separated from one another to provide discrete “chips” or destined for a packaged integrated circuit component. The individual dies 902, comprising an integrated circuit component, may include one or more transistors (e.g., some of the transistors 1040 of FIG. 10, discussed below), supporting circuitry to route electrical signals to the transistors, passive components (e.g., signal traces, resistors, capacitors, or inductors), and/or any other integrated circuit components. In some embodiments, the wafer 900 or the die 902 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Additionally, multiple devices may be combined on a single die 902. For example, a memory array formed by multiple memory devices may be formed on a same die 902 as a processor unit (e.g., the processor unit 1202 of FIG. 12) or other logic that is configured to store information in the memory devices or execute instructions stored in the memory array. In some embodiments, a die 902 may be attached to a wafer 900 that includes other die, and the wafer 900 is subsequently singulated, this manufacturing procedure is referred to as a die-to-wafer assembly technique.

FIG. 10 is a cross-sectional side view of an integrated circuit 1000 that may be included in any of the embodiments disclosed herein. One or more of the integrated circuits 1000 may be included in one or more dies 902 (FIG. 9). The integrated circuit 1000 may be formed on a die substrate 1002 (e.g., the wafer 900 of FIG. 9) and may be included in a die (e.g., the die 902 of FIG. 9).

The die substrate 1002 may be a semiconductor substrate composed of semiconductor material systems including, for example, n-type or p-type materials systems (or a combination of both). The die substrate 1002 may include, for example, a crystalline substrate formed using a bulk silicon or a silicon-on-insulator (SOI) substructure. In some embodiments, the die substrate 1002 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 1002. Although a few examples of materials from which the die substrate 1002 may be formed are described here, any material that may serve as a foundation for an integrated circuit 1000 may be used. The die substrate 1002 may be part of a singulated die (e.g., the dies 902 of FIG. 9) or a wafer (e.g., the wafer 900 of FIG. 9).

The integrated circuit 1000 may include one or more device layers 1004 disposed on the die substrate 1002. The device layer 1004 may include features of one or more transistors 1040 (e.g., metal oxide semiconductor field-effect transistors (MOSFETs)) formed on the die substrate 1002. The transistors 1040 may include, for example, one or more source and/or drain (S/D) regions 1020, a gate 1022 to control current flow between the S/D regions 1020, and one or more S/D contacts 1024 to route electrical signals to/from the S/D regions 1020.

The gate 1022 may be formed of at least two layers, a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be conducted on the gate dielectric to improve its quality when a high-k material is used.

The gate electrode may be formed on the gate dielectric and may include at least one p-type work function metal or n-type work function metal, depending on whether the transistor 1040 is to be a p-type metal oxide semiconductor (PMOS) or an n-type metal oxide semiconductor (NMOS) transistor. In some implementations, the gate electrode may comprise a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1040 along the source-channel-drain direction, the gate electrode may comprise a U-shaped structure that includes a bottom portion substantially parallel to the surface of the die substrate 1002 and two sidewall portions that are substantially perpendicular to the top surface of the die substrate 1002. In other embodiments, at least one of the metal layers that form the gate electrode may simply be a planar layer that is substantially parallel to the top surface of the die substrate 1002 and does not include sidewall portions substantially perpendicular to the top surface of the die substrate 1002. In other embodiments, the gate electrode may comprise a combination of U-shaped structures and planar, non-U-shaped structures. For example, the gate electrode may comprise one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and include deposition and etching processes. In some embodiments, a plurality of spacer pairs may be used; for instance, two pairs, three pairs, or four pairs of sidewall spacers may be formed on opposing sides of the gate stack.

The S/D regions 1020 may be formed within the die substrate 1002 adjacent to the gate 1022 of individual transistors 1040. The S/D regions 1020 may be formed using an implantation/diffusion process or an etching/deposition process, for example. In the former process, dopants such as boron, aluminum, antimony, phosphorous, or arsenic may be ion-implanted into the die substrate 1002 to form the S/D regions 1020. An annealing process that activates the dopants and causes them to diffuse farther into the die substrate 1002 may follow the ion-implantation process. In the latter process, the die substrate 1002 may first be etched to form recesses at the locations of the S/D regions 1020. An epitaxial deposition process may then be conducted to fill the recesses with material that is used to fabricate the S/D regions 1020. In some implementations, the S/D regions 1020 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1020 may be formed using one or more alternate semiconductor materials such as germanium or a group III-V material or alloy. In further embodiments, one or more layers of metal and/or metal alloys may be used to form the S/D regions 1020.

Electrical signals, such as power and/or input/output (I/O) signals, may be routed to and/or from the devices (e.g., transistors 1040) of the device layer 1004 through one or more interconnect layers disposed on the device layer 1004 (illustrated in FIG. 10 as interconnect layers 1006-1010). For example, electrically conductive features of the device layer 1004 (e.g., the gate 1022 and the S/D contacts 1024) may be electrically coupled with the interconnect structures 1028 of the interconnect layers 1006-1010. The one or more interconnect layers 1006-1010 may form a metallization stack (also referred to as an “ILD stack”) 1019 of the integrated circuit 1000.

The interconnect structures 1028 may be arranged within the interconnect layers 1006-1010 to route electrical signals according to a wide variety of designs; in particular, the arrangement is not limited to the particular configuration of interconnect structures 1028 depicted in FIG. 10. Although a particular number of interconnect layers 1006-1010 is depicted in FIG. 10, embodiments of the present disclosure include integrated circuits having more or fewer interconnect layers than depicted.

In some embodiments, the interconnect structures 1028 may include lines 1028a and/or vias 1028b filled with an electrically conductive material such as a metal. The lines 1028a may be arranged to route electrical signals in a direction of a plane that is substantially parallel with a surface of the die substrate 1002 upon which the device layer 1004 is formed. For example, the lines 1028a may route electrical signals in a direction in and out of the page and/or in a direction across the page. The vias 1028b may be arranged to route electrical signals in a direction of a plane that is substantially perpendicular to the surface of the die substrate 1002 upon which the device layer 1004 is formed. In some embodiments, the vias 1028b may electrically couple lines 1028a of different interconnect layers 1006-1010 together.

The interconnect layers 1006-1010 may include a dielectric material 1026 disposed between the interconnect structures 1028, as shown in FIG. 10. In some embodiments, dielectric material 1026 disposed between the interconnect structures 1028 in different ones of the interconnect layers 1006-1010 may have different compositions; in other embodiments, the composition of the dielectric material 1026 between different interconnect layers 1006-1010 may be the same. The device layer 1004 may include a dielectric material 1026 disposed between the transistors 1040 and a bottom layer of the metallization stack as well. The dielectric material 1026 included in the device layer 1004 may have a different composition than the dielectric material 1026 included in the interconnect layers 1006-1010; in other embodiments, the composition of the dielectric material 1026 in the device layer 1004 may be the same as a dielectric material 1026 included in any one of the interconnect layers 1006-1010.

A first interconnect layer 1006 (referred to as Metal 1 or “M1”) may be formed directly on the device layer 1004. In some embodiments, the first interconnect layer 1006 may include lines 1028a and/or vias 1028b, as shown. The lines 1028a of the first interconnect layer 1006 may be coupled with contacts (e.g., the S/D contacts 1024) of the device layer 1004. The vias 1028b of the first interconnect layer 1006 may be coupled with the lines 1028a of a second interconnect layer 1008.

The second interconnect layer 1008 (referred to as Metal 2 or “M2”) may be formed directly on the first interconnect layer 1006. In some embodiments, the second interconnect layer 1008 may include via 1028b to couple the lines 1028 of the second interconnect layer 1008 with the lines 1028a of a third interconnect layer 1010. Although the lines 1028a and the vias 1028b are structurally delineated with a line within individual interconnect layers for the sake of clarity, the lines 1028a and the vias 1028b may be structurally and/or materially contiguous (e.g., simultaneously filled during a dual-damascene process) in some embodiments.

The third interconnect layer 1010 (referred to as Metal 3 or “M3”) (and additional interconnect layers, as desired) may be formed in succession on the second interconnect layer 1008 according to similar techniques and configurations described in connection with the second interconnect layer 1008 or the first interconnect layer 1006. In some embodiments, the interconnect layers that are “higher up” in the metallization stack 1019 in the integrated circuit 1000 (i.e., farther away from the device layer 1004) may be thicker that the interconnect layers that are lower in the metallization stack 1019, with lines 1028a and vias 1028b in the higher interconnect layers being thicker than those in the lower interconnect layers.

The integrated circuit 1000 may include a solder resist material 1034 (e.g., polyimide or similar material) and one or more conductive contacts 1036 formed on the interconnect layers 1006-1010. In FIG. 10, the conductive contacts 1036 are illustrated as taking the form of bond pads. The conductive contacts 1036 may be electrically coupled with the interconnect structures 1028 and configured to route the electrical signals of the transistor(s) 1040 to external devices. For example, solder bonds may be formed on the one or more conductive contacts 1036 to mechanically and/or electrically couple an integrated circuit die including the integrated circuit 1000 with another component (e.g., a printed circuit board). The integrated circuit 1000 may include additional or alternate structures to route the electrical signals from the interconnect layers 1006-1010; for example, the conductive contacts 1036 may include other analogous features (e.g., posts) that route the electrical signals to external components.

In some embodiments in which the integrated circuit 1000 is a double-sided die, the integrated circuit 1000 may include another metallization stack (not shown) on the opposite side of the device layer(s) 1004. This metallization stack may include multiple interconnect layers as discussed above with reference to the interconnect layers 1006-1010, to provide electrically conductive paths (e.g., including conductive lines and vias) between the device layer(s) 1004 and additional conductive contacts (not shown) on the opposite side of the integrated circuit 1000 from the conductive contacts 1036.

In other embodiments in which the integrated circuit 1000 is a double-sided die, the integrated circuit 1000 may include one or more through-silicon vias (TSVs) through the die substrate 1002; these TSVs may make contact with the device layer(s) 1004, and may provide electrically conductive paths between the device layer(s) 1004 and additional conductive contacts (not shown) on the opposite side of the integrated circuit 1000 from the conductive contacts 1036. In some embodiments, TSVs extending through the substrate can be used for routing power and ground signals from conductive contacts on the opposite side of the integrated circuit 1000 from the conductive contacts 1036 to the transistors 1040 and any other components integrated into the die 1000, and the metallization stack 1019 can be used to route I/O signals from the conductive contacts 1036 to transistors 1040 and any other components integrated into the die 1000.

Multiple integrated circuits 1000 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

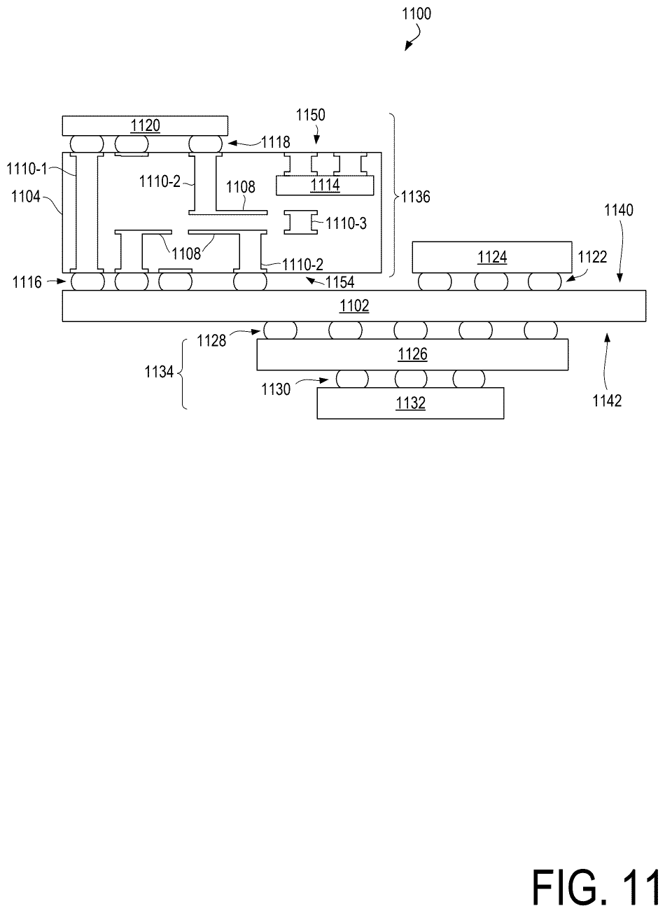

FIG. 11 is a cross-sectional side view of a microelectronic assembly 1100 that may include any of the embodiments disclosed herein. The microelectronic assembly 1100 includes multiple integrated circuit components disposed on a circuit board 1102 (which may be a motherboard, system board, mainboard, etc.). The microelectronic assembly 1100 may include components disposed on a first face 1140 of the circuit board 1102 and an opposing second face 1142 of the circuit board 1102; generally, components may be disposed on one or both faces 1140 and 1142.

In some embodiments, the circuit board 1102 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 1102. In other embodiments, the circuit board 1102 may be a non-PCB substrate. The microelectronic assembly 1100 illustrated in FIG. 11 includes a package-on-interposer structure 1136 coupled to the first face 1140 of the circuit board 1102 by coupling components 1116. The coupling components 1116 may electrically and mechanically couple the package-on-interposer structure 1136 to the circuit board 1102, and may include solder balls (as shown in FIG. 11), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 1136 may include an integrated circuit component 1120 coupled to an interposer 1104 by coupling components 1118. The coupling components 1118 may take any suitable form for the application, such as the forms discussed above with reference to the coupling components 1116. Although a single integrated circuit component 1120 is shown in FIG. 11, multiple integrated circuit components may be coupled to the interposer 1104; indeed, additional interposers may be coupled to the interposer 1104. The interposer 1104 may provide an intervening substrate used to bridge the circuit board 1102 and the integrated circuit component 1120.

The integrated circuit component 1120 may be a packaged or unpackaged integrated circuit component that includes one or more integrated circuit dies (e.g., the die 902 of FIG. 9, the integrated circuit 1000 of FIG. 10) and/or one or more other suitable components.

The unpackaged integrated circuit component 1120 comprises solder bumps attached to contacts on the die. The solder bumps allow the die to be directly attached to the interposer 1104. In embodiments where the integrated circuit component 1120 comprises multiple integrated circuit die, the dies can be of the same type (a homogeneous multi-die integrated circuit component) or of two or more different types (a heterogeneous multi-die integrated circuit component). In addition to comprising one or more processor units, the integrated circuit component 1120 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate, or combinations thereof. A packaged multi-die integrated circuit component can be referred to as a multi-chip package (MCP) or multi-chip module (MCM).

The interposer 1104 may spread connections to a wider pitch or reroute a connection to a different connection. For example, the interposer 1104 may couple the integrated circuit component 1120 to a set of ball grid array (BGA) conductive contacts of the coupling components 1116 for coupling to the circuit board 1102. In the embodiment illustrated in FIG. 11, the integrated circuit component 1120 and the circuit board 1102 are attached to opposing sides of the interposer 1104; in other embodiments, the integrated circuit component 1120 and the circuit board 1102 may be attached to a same side of the interposer 1104. In some embodiments, three or more components may be interconnected by way of the interposer 1104.

In some embodiments, the interposer 1104 may be formed as a PCB, including multiple metal layers separated from one another by layers of dielectric material and interconnected by electrically conductive vias. In some embodiments, the interposer 1104 may be formed of an epoxy resin, a fiberglass-reinforced epoxy resin, an epoxy resin with inorganic fillers, a ceramic material, or a polymer material such as polyimide. In some embodiments, the interposer 1104 may be formed of alternate rigid or flexible materials that may include the same materials described above for use in a semiconductor substrate, such as silicon, germanium, and other group III-V and group IV materials. The interposer 1104 may include metal interconnects 1108 and vias 1110, including but not limited to through hole vias 1110-1 (that extend from a first face 1150 of the interposer 1104 to a second face 1154 of the interposer 1104), blind vias 1110-2 (that extend from the first or second faces 1150 or 1154 of the interposer 1104 to an internal metal layer), and buried vias 1110-3 (that connect internal metal layers).

In some embodiments, the interposer 1104 can comprise a silicon interposer. Through-silicon vias (TSV) extending through the silicon interposer can connect connections on the first face of a silicon interposer to an opposing second face of the silicon interposer. In some embodiments, an interposer 1104 comprising a silicon interposer can further comprise one or more routing layers to route connections on a first face of the interposer 1104 to an opposing second face of the interposer 1104.

The interposer 1104 may further include embedded devices 1114, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1104. The package-on-interposer structure 1136 may take the form of any of the package-on-interposer structures known in the art.

The integrated circuit assembly 1100 may include an integrated circuit component 1124 coupled to the first face 1140 of the circuit board 1102 by coupling components 1122. The coupling components 1122 may take the form of any of the embodiments discussed above with reference to the coupling components 1116, and the integrated circuit component 1124 may take the form of any of the embodiments discussed above with reference to the integrated circuit component 1120.

The integrated circuit assembly 1100 illustrated in FIG. 11 includes a package-on-package structure 1134 coupled to the second face 1142 of the circuit board 1102 by coupling components 1128. The package-on-package structure 1134 may include an integrated circuit component 1126 and an integrated circuit component 1132 coupled together by coupling components 1130 such that the integrated circuit component 1126 is disposed between the circuit board 1102 and the integrated circuit component 1132. The coupling components 1128 and 1130 may take the form of any of the embodiments of the coupling components 1116 discussed above, and the integrated circuit components 1126 and 1132 may take the form of any of the embodiments of the integrated circuit component 1120 discussed above. The package-on-package structure 1134 may be configured in accordance with any of the package-on-package structures known in the art.

FIG. 12 is a block diagram of an example electrical device 1200 that may include one or more of the embodiments disclosed herein. For example, any suitable ones of the components of the electrical device 1200 may include one or more of the microelectronic assemblies 1100, integrated circuit components 1120, integrated circuits 1000, integrated circuit dies 902, or structures disclosed herein. A number of components are illustrated in FIG. 12 as included in the electrical device 1200, but any one or more of these components may be omitted or duplicated, as suitable for the application. In some embodiments, some or all the components included in the electrical device 1200 may be attached to one or more motherboards, mainboards, printed circuit boards, or system boards. In some embodiments, one or more of these components are fabricated onto a single system-on-a-chip (SoC) die. In various embodiments, the electrical device 3000 is enclosed by, or integrated with, a housing.

Additionally, in various embodiments, the electrical device 1200 may not include one or more of the components illustrated in FIG. 12, but the electrical device 1200 may include interface circuitry for coupling to the one or more components. For example, the electrical device 1200 may not include a display device 1206, but may include display device interface circuitry (e.g., a connector and driver circuitry) to which a display device 1206 may be coupled. In another set of examples, the electrical device 1200 may not include an audio input device 1224 or an audio output device 1208, but may include audio input or output device interface circuitry (e.g., connectors and supporting circuitry) to which an audio input device 1224 or audio output device 1208 may be coupled.

The electrical device 1200 may include one or more processor units 1202 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1202 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller crypto processors (specialized processors that execute cryptographic algorithms within hardware), server processors, controllers, or any other suitable type of processor units. As such, the processor unit can be referred to as an XPU (or xPU).

The electrical device 1200 may include a memory 1204, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1204 may include memory that is located on the same integrated circuit die as the processor unit 1202. This memory may be used as cache memory (e.g., Level 1 (L1), Level 2 (L2), Level 3 (L3), Level 4 (L4), Last Level Cache (LLC)) and may include embedded dynamic random-access memory (eDRAM) or spin transfer torque magnetic random-access memory (STT-MRAM).

In some embodiments, the electrical device 1200 can comprise one or more processor units 1202 that are heterogeneous or asymmetric to another processor unit 1202 in the electrical device 1200. There can be a variety of differences between the processor units 1202 in a system in terms of a spectrum of metrics of merit including architectural, microarchitectural, thermal, power consumption characteristics, and the like. These differences can effectively manifest themselves as asymmetry and heterogeneity among the processor units 1202 in the electrical device 1200.

In some embodiments, the electrical device 1200 may include a communication component 1212 (e.g., one or more communication components). For example, the communication component 1212 can manage wireless communications for the transfer of data to and from the electrical device 1200. The term “wireless” and its derivatives may be used to describe circuits, devices, systems, methods, techniques, communications channels, etc., that may communicate data using modulated electromagnetic radiation through a nonsolid medium. The term “wireless” does not imply that the associated devices do not contain any wires, although in some embodiments they might not.

The communication component 1212 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra-mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1212 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1212 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1212 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1212 may operate in accordance with other wireless protocols in other embodiments. The electrical device 1200 may include an antenna 1222 to facilitate wireless communications and/or to receive other wireless communications (such as AM or FM radio transmissions).

In some embodiments, the communication component 1212 may manage wired communications, such as electrical, optical, or any other suitable communication protocols (e.g., IEEE 802.3 Ethernet standards). As noted above, the communication component 1212 may include multiple communication components. For instance, a first communication component 1212 may be dedicated to shorter-range wireless communications such as Wi-Fi or Bluetooth, and a second communication component 1212 may be dedicated to longer-range wireless communications such as global positioning system (GPS), EDGE, GPRS, CDMA, WiMAX, LTE, EV-DO, or others. In some embodiments, a first communication component 1212 may be dedicated to wireless communications, and a second communication component 1212 may be dedicated to wired communications.

The electrical device 1200 may include battery/power circuitry 1214. The battery/power circuitry 1214 may include one or more energy storage devices (e.g., batteries or capacitors) and/or circuitry for coupling components of the electrical device 1200 to an energy source separate from the electrical device 1200 (e.g., AC line power).

The electrical device 1200 may include a display device 1206 (or corresponding interface circuitry, as discussed above). The display device 1206 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1200 may include an audio output device 1208 (or corresponding interface circuitry, as discussed above). The audio output device 1208 may include any embedded or wired or wirelessly connected external device that generates an audible indicator, such speakers, headsets, or earbuds.

The electrical device 1200 may include an audio input device 1224 (or corresponding interface circuitry, as discussed above). The audio input device 1224 may include any embedded or wired or wirelessly connected device that generates a signal representative of a sound, such as microphones, microphone arrays, or digital instruments (e.g., instruments having a musical instrument digital interface (MIDI) output). The electrical device 1200 may include a Global Navigation Satellite System (GNSS) device 1218 (or corresponding interface circuitry, as discussed above), such as a Global Positioning System (GPS) device. The GNSS device 1218 may be in communication with a satellite-based system and may determine a geolocation of the electrical device 1200 based on information received from one or more GNSS satellites, as known in the art.

The electrical device 1200 may include another output device 1210 (or corresponding interface circuitry, as discussed above). Examples of the other output device 1210 may include an audio codec, a video codec, a printer, a wired or wireless transmitter for providing information to other devices, or an additional storage device.

The electrical device 1200 may include another input device 1220 (or corresponding interface circuitry, as discussed above). Examples of the other input device 1220 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1200 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra-mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1200 may be any other electronic device that processes data. In some embodiments, the electrical device 1200 may comprise multiple discrete physical components. Given the range of devices that the electrical device 1200 can be manifested as in various embodiments, in some embodiments, the electrical device 1200 can be referred to as a computing device or a computing system.

While at least one embodiment has been presented in the foregoing detailed description, it should be appreciated that a vast number of variations exist. It should also be appreciated that the disclosed embodiments are only examples, and are not intended to limit the scope, applicability, or configuration of the disclosure in any way. Rather, the foregoing detailed description will provide those skilled in the art with a convenient road map for implementing the disclosed embodiment embodiments. Various changes can be made in the function and arrangement of elements without departing from the scope of the disclosure as set forth in the appended claims and the legal equivalents thereof.

As used herein, phrases such as “an embodiment,” “various embodiments,” “some embodiments,” and the like, indicate that some embodiments may have some, all, or none of the features described for other embodiments. “First,” “second,” “third,” and the like describe a common object and indicate different instances of like objects being referred to; unless specifically stated, they do not imply a given sequence, either temporally or spatially, in ranking, or any other manner. In accordance with patent application parlance, “connected” indicates elements that are in direct physical or electrical contact with each other and “coupled” indicates elements that co-operate or interact with each other, coupled elements may or may not be in direct physical or electrical contact. Furthermore, the terms “comprising,” “including,” “having,” and the like, are utilized synonymously to denote non-exclusive inclusions.

As used in this application and the claims, a list of items joined by the term “at least one of” or the term “one or more of” can mean any combination of the listed terms. For example, the phrase “at least one of A, B or C” can mean A; B; C; A and B; A and C; B and C; or A, B, and C. Likewise, the phrase “one or more of A, B and C” can mean A; B; C; A and B; A and C; B and C; or A, B, and C.

As used in this application and the claims, the phrase “individual of” or “respective of” following by a list of items recited or stated as having a trait, feature, etc., means that all the items in the list possess the stated or recited trait, feature, etc. For example, the phrase “individual of A, B, or C, comprise a sidewall” or “respective of A, B, or C, comprise a sidewall” means that A comprises a sidewall, B comprises sidewall, and C comprises a sidewall.

Theories of operation, scientific principles, or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

Unless otherwise stated, terms or values modified by the word “substantially” include arrangements, orientations, spacings, or positions that vary plus or minus 20% from the meaning of the unmodified term or value. Terms or values modified by the word “about” include values inclusive of 10% less than the term or value to inclusive of 10% greater than the term or value.

As used herein, the term “electronic component” can refer to an active electronic circuit (e.g., processing unit, memory, storage device, FET) or a passive electronic circuit (e.g., resistor, inductor, capacitor).

As used herein, the term “integrated circuit component” can refer to an electronic component configured on a semiconducting material to perform a function. An integrated circuit (IC) component can comprise one or more of any computing system components described or referenced herein or any other computing system component, such as a processor unit (e.g., system-on-a-chip (SoC), processor core, graphics processor unit (GPU), accelerator, chipset processor), I/O controller, memory, or network interface controller, and can comprise one or more additional active or passive devices such as capacitors, decoupling capacitors, resistors, inductors, fuses, diodes, transformers, sensors, electrostatic discharge (ESD) devices, and memory devices.

A non-limiting example of an unpackaged integrated circuit component includes a single monolithic integrated circuit die (shortened herein to “die”); the die may include solder bumps attached to contacts on the die. When present on the die, the solder bumps or other conductive contacts can enable the die to be directly attached to a printed circuit board (PCB) or other substrates.

A non-limiting example of a packaged integrated circuit component comprises one or more integrated circuit dies mounted on a package substrate with the integrated circuit dies and package substrate encapsulated in a casing material, such as a metal, plastic, glass, or ceramic. Often the casing includes an integrated heat spreader (IHS); the packaged integrated circuit component often has bumps, leads, or pins attached to the package substrate (either directly or by wires attaching the bumps, leads, or pins to the package substrate) for attaching the packaged integrated circuit component to a printed circuit board (or motherboard or base board) or another component.

The following examples pertain to additional embodiments of technologies disclosed herein.

### Examples

Example 1 is a substrate package component, comprising: a layer of glass comprising a rectangular prism volume defined by a planar area and a perimeter edge; a through-glass via (TGV) in the layer of glass, the TGV substantially filled with a conductive material; a frame surrounding the perimeter edge; and a mold material between the frame and the perimeter edge.

Example 2 includes the subject matter of Example 1, wherein: the frame comprises a material with a coefficient of thermal expansion (CTE) less than 11.

Example 3 includes the subject matter of Example 1 or Example 2, wherein: the frame comprises Kovar®, Invar®, or stainless steel®.

Example 4 includes the subject matter of Example 1 or Example 2, wherein: the frame comprises Copper and Tungsten, with between 11% and 99% Copper.

Example 5 includes the subject matter of Example 1 or Example 2, wherein: the frame comprises Copper and Tungsten, with between 20% and 50% Copper.

Example 6 includes the subject matter of Example 4 or Example 5, wherein the frame further comprises glass fibers and a resin.

Example 7 includes the subject matter of any one of Examples 1-6, wherein the layer of glass comprises a first thickness in a range of 20 microns+/−20% to 2 millimeters+/−20%, and the frame comprises a second thickness in a range of 200 microns+/−10% to 3 mm+/−10%.

Example 8 includes the subject matter of any one of Examples 1-6, wherein the frame comprises a thickness in a range of 100 microns+/−10% to 5 mm+/−10%, and a width in a range of 2 millimeters (mm)+/−10% to 15 mm+/−10%.

Example 9 includes the subject matter of any one of Examples 1-6, wherein the frame comprises a thickness in a range of 100 microns+/−10% to 5 mm+/−10%, and a width in a range of 0.5 millimeters (mm)+/−10% to 20 mm+/−10%.

Example 10 includes the subject matter of any one of Examples 1-9, wherein: the planar area comprises a diameter of 100 mm+/−20% to 300 mm+/−20%.

Example 11 includes the subject matter of any one of Examples 1-9, wherein: the perimeter edge comprises a first edge with a length of less than or equal to 500 millimeters (mm)+10% and a second edge perpendicular to the first edge, the second edge has a length of less than or equal to 500 mm+10%.

Example 12 includes the subject matter of any one of Examples 1-11, further comprising: a dielectric material on a first surface of the layer of glass; and redistribution layers (RDL) within the dielectric material.

Example 13 includes the subject matter of Example 1, further comprising a carrier layer releasably attached to the layer of glass and the frame.

Example 14 is an apparatus, comprising: a system, comprising: a layer of glass comprising a rectangular prism volume defined by an upper surface, a lower surface, and a perimeter edge; a plurality of through-glass vias (TGVs) arranged in the layer of glass between the upper surface and lower surface, individual TGVs of the plurality of TGVs substantially filled with a conductive material; a first dielectric layer on the upper surface, the first dielectric layer comprising conductive traces and vias therein; and at least one integrated circuit (IC) die attached the first dielectric layer; a frame comprising a material with a coefficient of thermal expansion (CTE) less than 11, the frame enclosing at least part of the perimeter edge; and a dielectric material between the frame and the perimeter edge.

Example 15 includes the subject matter of Example 14, wherein: the system is one of a plurality of systems reconstituted into a wafer, such that adjacent systems have at least a portion with a shared frame; and the wafer has a diameter of 100 mm+/−20% to 300 mm+/−20.

Example 16 includes the subject matter of Example 14, wherein: the system is one of a plurality of systems reconstituted into a panel, such that adjacent systems have at least a portion with a shared frame; the panel has a width of less than or equal to 500 millimeters (mm)+10% and a length of less than or equal to 500 mm+10%.

Example 17 includes the subject matter of any one of Examples 14-16, wherein: the frame comprises Kovar®, Invar®, or Stainless Steel®.

Example 18 includes the subject matter of any one of Examples 14-16, wherein: the frame comprises Copper and Tungsten, with between 11% and 99% Copper.

Example 19 includes the subject matter of any one of Examples 14-16, wherein: the frame comprises Copper and Tungsten, with between 20% and 50% copper.

Example 20 is a method, comprising: creating a frame comprising a material with a coefficient of thermal expansion of less than 11; wherein the frame includes one or more cavities characterized by continuous sidewalls and open at a top and a bottom; placing the frame on a carrier; placing a glass core into a cavity of the one or more cavities in the frame on the carrier; applying a dielectric material on an upper surface of the glass core and between the glass core and sidewalls of the frame; removing the carrier; planarizing an upper surface of the dielectric material; and completing substrate fabrication of the glass core to create a substrate package.

Example 21 includes the subject matter of Example 20, wherein the frame is created to have a thickness in a range of 200 microns+/−10% to 3 mm+/−10%.

Example 22 includes the subject matter of Example 20, wherein the frame is created to have a width in a range of 2 millimeters (mm)+/−10% to 15 mm+/−10%.

Example 23 includes the subject matter of Example 20, wherein the frame is created to have a planar area diameter of 100 mm+/−20% to 300 mm+/−20%.

Example 24 includes the subject matter of Example 20, wherein the frame is created to have a perimeter edge comprising a first edge with a length of less than or equal to 500 millimeters (mm)+10% and a second edge perpendicular to the first edge, the second edge has a length of less than or equal to 500 mm+10%.

Example 25 includes the subject matter of Example 20, further comprising dicing the frame to singulate the substrate package.

What is claimed is:

1. A substrate package component, comprising:
a layer of glass comprising a rectangular prism volume defined by a planar area and a perimeter edge;
a through-glass via (TGV) in the layer of glass, the TGV substantially filled with a conductive material;
a frame surrounding the perimeter edge; and
a mold material between the frame and the perimeter edge.

2. The substrate package component of claim 1, wherein:
the frame comprises a material with a coefficient of thermal expansion (CTE) less than 11.

3. The substrate package component of claim 1, wherein:
the frame comprises Kovar®, Invar®, or stainless steel®.

4. The substrate package component of claim 1, wherein:
the frame comprises Copper and Tungsten, with between 11% and 99% Copper.

5. The substrate package component of claim 1, wherein:
the frame comprises Copper and Tungsten, with between 20% and 50% Copper.

6. The substrate package component of claim 5, wherein the frame further comprises glass fibers and a resin.

7. The substrate package component of claim 1, wherein the layer of glass comprises a first thickness in a range of 20 microns+/−20% to 2 millimeters+/−20%, and the frame comprises a second thickness in a range of 200 microns+/−10% to 3 mm+/−10%.

8. The substrate package component of claim 1, wherein the frame comprises a thickness in a range of 100 microns+/−10% to 5 mm+/−10%, and a width in a range of 2 millimeters (mm)+/−10% to 15 mm+/−10%.

9. The substrate package component of claim 1, wherein the frame comprises a thickness in a range of 100 microns+/−10% to 5 mm+/−10%, and a width in a range of 0.5 millimeters (mm)+/−10% to 20 mm+/−10%.

10. The substrate package component of claim 1, wherein:
the planar area comprises a diameter of 100 mm+/−20% to 300 mm+/−20%.

11. The substrate package component of claim 1, wherein:
the perimeter edge comprises a first edge with a length of less than or equal to 500 millimeters (mm)+10% and a second edge perpendicular to the first edge, the second edge has a length of less than or equal to 500 mm+10%.

12. The substrate package component of claim 1, further comprising:
a dielectric material on a first surface of the layer of glass; and
redistribution layers (RDL) within the dielectric material.

13. The substrate package component of claim 1, further comprising a carrier layer releasably attached to the layer of glass and the frame.

14. An apparatus, comprising:
a system, comprising:
a layer of glass comprising a rectangular prism volume defined by an upper surface, a lower surface, and a perimeter edge;
a plurality of through-glass vias (TGVs) arranged in the layer of glass between the upper surface and lower surface, individual TGVs of the plurality of TGVs substantially filled with a conductive material;
a first dielectric layer on the upper surface, the first dielectric layer comprising conductive traces and vias therein; and
at least one integrated circuit (IC) die attached the first dielectric layer;
a frame comprising a material with a coefficient of thermal expansion (CTE) less than 11, the frame enclosing at least part of the perimeter edge; and
a dielectric material between the frame and the perimeter edge.

15. The apparatus of claim 14, wherein:
the system is one of a plurality of systems reconstituted into a wafer, such that adjacent systems have at least a portion with a shared frame; and
the wafer has a diameter of 100 mm+/−20% to 300 mm+/−20.

16. The apparatus of claim 14, wherein:
the system is one of a plurality of systems reconstituted into a panel, such that adjacent systems have at least a portion with a shared frame;
the panel has a width of less than or equal to 500 millimeters (mm)+10% and a length of less than or equal to 500 mm+10%.

17. The apparatus of claim 14, wherein:
the frame comprises Kovar®, Invar®, or Stainless Steel®.

18. The apparatus of claim 14, wherein:
the frame comprises Copper and Tungsten, with between 11% and 99% Copper.

19. The apparatus of claim 14, wherein:
the frame comprises Copper and Tungsten, with between 20% and 50% copper.

20. A method, comprising:
creating a frame comprising a material with a coefficient of thermal expansion of less than 11;
wherein the frame includes one or more cavities characterized by continuous sidewalls and open at a top and a bottom;
placing the frame on a carrier;
placing a glass core into a cavity of the one or more cavities in the frame on the carrier;
applying a dielectric material on an upper surface of the glass core and between the glass core and sidewalls of the frame;
removing the carrier;
planarizing an upper surface of the dielectric material; and
completing substrate fabrication of the glass core to create a substrate package.
